(19) United States
(12) Patent Application Publication
(10) Pub. No.: US 2025/0311171 A1
(43) Pub. Date: Oct. 2, 2025

(54) SOLENOID VALVE USAGE IN OPEN LOOP LIQUID COOLING

(71) Applicant: Cisco Technology, Inc., San Jose, CA (US)

(72) Inventors: Rakesh Bhatia, San Jose, CA (US); Stephen A. Scearce, Cary, NC (US); Phong Ho, Cary, NC (US)

(21) Appl. No.: 18/622,687

(22) Filed: Mar. 29, 2024

(51) Int. Cl. H05K 7/20

(52) U.S. Cl. CPC H05K 7/20836; H05K 7/20272; H05K 7/20772

(57) ABSTRACT

Described herein are devices, systems, methods, and processes for enhancing the fault tolerance and efficiency of open loop liquid cooling systems in high-powered computing environments. A leak detector is integrated, which, upon detecting a leak, may signal the baseboard management controller to shut down the coolant flow in the affected section by closing corresponding solenoid valves, preventing a complete system shutdown. The solenoid valves and the leak detector may be part of an on-board cooling system within the server chassis, providing localized control and fault tolerance. Additionally, the system can utilize the solenoid valves to control the coolant flow rate based on the thermal load of the device, optimizing energy usage, and potentially allowing for a higher number of devices within a rack. The embodiments may offer a more resilient and energy-efficient liquid cooling system for devices including high-powered components.

The present disclosure relates to liquid cooling systems. More particularly, the present disclosure relates to an open loop liquid cooling system with leak detection and controlled coolant flow at a chassis level.

### BACKGROUND

Liquid cooling systems are becoming commonplace in computing devices that include such high-powered components as application-specific integrated circuits (ASICs), central processing units (CPUs), and graphics processing units (GPUs). The liquid cooling systems may utilize a coolant to absorb and dissipate heat generated by these components. However, managing coolant leaks in these systems can present a significant challenge.

In existing liquid cooling systems, while some may incorporate leak detection mechanisms, these are typically limited to powering off the computing devices. They do not provide a means to halt the leak, resulting in the coolant continuing to spill until manual intervention occurs. This can lead to severe damage to the system and surrounding equipment, and in large-scale environments like data centers, immediate manual intervention may not be feasible, leading to potentially catastrophic outcomes.

Moreover, existing systems may lack the ability to control or stop the coolant at the level of the individual server chassis or enclosure. This means that when a leak occurs, it can impact the entire rack or system, rather than being confined to the specific server where the leak originated. This lack of localized control can exacerbate the damage and disruption caused by a coolant leak.

Additionally, many existing systems operate with a constant coolant flow rate, irrespective of the thermal load of the device. This can lead to inefficiencies, as the pump may be working harder than necessary when the power usage of the device is lower than its maximum possible level. The constant flow rate can also result in a closed-loop system with an over-capacity design, leading to unnecessary costs and space usage.

### SUMMARY OF THE DISCLOSURE

Systems and methods for open loop liquid cooling system with leak detection and controlled coolant flow at a chassis level in accordance with embodiments of the disclosure are described herein. In some embodiments, a device includes a processor, at least one network interface controller configured to provide access to a network, and a memory communicatively coupled to the processor, wherein the memory includes a liquid cooling management logic that is configured to determine a condition of the device; and adjust a state of one or more hydraulic solenoid valves to effect a change in a coolant flow in the device based on the determined condition of the device, wherein the device is associated with a liquid cooling system for a device enclosure that is mountable in a server rack.

In some embodiments, the processor is associated with a baseboard management controller.

In some embodiments, the device further includes a leak detector, and determining the condition of the device includes detecting a coolant leak in the device based on the leak detector.

In some embodiments, adjusting the state of the one or more hydraulic solenoid valves to effect the change in the coolant flow includes causing at least one of the one or more hydraulic solenoid valves to close to stop the coolant flow in the device based on the detected coolant leak.

In some embodiments, the leak detector includes a single wire leak detector.

In some embodiments, the leak detector includes a millimeter wave-based leak detector.

In some embodiments, the leak detector includes a time-domain reflectometry-based leak detector.

In some embodiments, the leak detector includes a vector network analyzer-based leak detector.

In some embodiments, the at least one of the one or more hydraulic solenoid valves includes a hydraulic solenoid valve on a coolant inlet line of the device.

In some embodiments, the at least one of the one or more hydraulic solenoid valves includes a first hydraulic solenoid valve on a coolant inlet line of the device and a second hydraulic solenoid valve on a coolant outlet line of the device.

In some embodiments, at least one of the one or more hydraulic solenoid valves are inside the device enclosure.

In some embodiments, at least one of the one or more hydraulic solenoid valves are outside the device enclosure.

In some embodiments, the device enclosure includes a blade chassis.

In some embodiments, the device enclosure includes a rack chassis.

In some embodiments, the device is associated with an open loop liquid cooling system.

In some embodiments, the condition of the device includes a thermal load in the device enclosure, and wherein adjusting the state of the one or more hydraulic solenoid valves to effect the change in the coolant flow includes adjusting the state of the one or more hydraulic solenoid valves to change a coolant flow rate based on the thermal load.

In some embodiments, the liquid cooling management logic is further configured to compare the thermal load to a threshold, and adjusting the state of the one or more hydraulic solenoid valves to change the coolant flow rate based on the thermal load further includes reducing the coolant flow rate in response to the thermal load being less than the threshold.

In some embodiments, a liquid cooling management logic is configured to detect a coolant leak in the device based on a leak detector, and cause one or more hydraulic solenoid valves to close to stop a coolant flow in the device based on the detected coolant leak, wherein the device corresponds to a liquid cooling system for a device enclosure that is mountable in a server rack.

In some embodiments, the leak detector includes a millimeter wave-based leak detector.

In some embodiments, a method includes receiving an indication of a condition of a liquid cooling system associated with a device enclosure, wherein the device enclosure is mountable in a server rack, determining whether the condition includes at least one of a coolant leak or a change in a thermal load, and transmitting a signal based on the determination to the liquid cooling system associated with the device enclosure.

Other objects, advantages, novel features, and further scope of applicability of the present disclosure will be set forth in part in the detailed description to follow, and in part will become apparent to those skilled in the art upon examination of the following or may be learned by practice of the disclosure. Although the description above contains many specificities, these should not be construed as limiting the scope of the disclosure but as merely providing illustrations of some of the presently preferred embodiments of the disclosure. As such, various other embodiments are possible within its scope. Accordingly, the scope of the disclosure should be determined not by the embodiments illustrated, but by the appended claims and their equivalents.

### BRIEF DESCRIPTION OF DRAWINGS

The above, and other, aspects, features, and advantages of several embodiments of the present disclosure will be more apparent from the following description as presented in conjunction with the following several figures of the drawings.

FIG. 1 is a diagram illustrating an open loop liquid cooling system implementation in a rack in accordance with various embodiments of the disclosure;

FIG. 2 is a diagram illustrating single wire leak detection in accordance with various embodiments of the disclosure;

FIG. 3 is a diagram illustrating a top view of the placement of solenoid valves in the device enclosure-associated liquid cooling system within a blade chassis in accordance with various embodiments of the disclosure;

FIG. 4 is a diagram illustrating a top view of the placement of solenoid valves in the device enclosure-associated liquid cooling system within a rack chassis in accordance with various embodiments of the disclosure;

FIG. 5 is a diagram illustrating the placement of solenoid valves on the coolant lines of a coolant distribution manifold in accordance with various embodiments of the disclosure;

FIG. 6 is a diagram illustrating the interaction between various components in a device enclosure-associated liquid cooling system in accordance with various embodiments of the disclosure;

FIG. 7 is a flowchart showing a process for managing a device enclosure-associated liquid cooling system in accordance with various embodiments of the disclosure;

FIG. 8 is a flowchart showing a process for managing a device enclosure-associated liquid cooling system based on thermal load in accordance with various embodiments of the disclosure;

FIG. 9 is a flowchart showing a process for managing a device enclosure-associated liquid cooling system within a rack by an external controller in accordance with various embodiments of the disclosure;

FIG. 10 is a flowchart showing a process for managing a device enclosure-associated liquid cooling system in accordance with various embodiments of the disclosure;

FIG. 11 is a flowchart showing a process for managing a device enclosure-associated liquid cooling system in accordance with various embodiments of the disclosure; and

FIG. 12 is a conceptual block diagram for one or more devices capable of executing components and logic for implementing the functionality and embodiments described above.

Corresponding reference characters indicate corresponding components throughout the several figures of the drawings. Elements in the several figures are illustrated for simplicity and clarity and have not necessarily been drawn to scale. For example, the dimensions of some of the elements in the figures might be emphasized relative to other elements for facilitating understanding of the various presently disclosed embodiments. In addition, common, but well-understood, elements that are useful or necessary in a commercially feasible embodiment are often not depicted in order to facilitate a less obstructed view of these various embodiments of the present disclosure.

### DETAILED DESCRIPTION

In response to the issues described above, devices and methods are discussed herein that enhance the fault tolerance and efficiency of open loop liquid cooling systems for high-powered computing devices. This may be achieved through the use of hydraulic solenoid valves to control the coolant flow rate and a leak detector to detect and respond to coolant leaks. In many embodiments, an open loop liquid cooling system may include a pump that circulates a liquid coolant through tubes or channels. The tubes can pass over the high-powered components where the coolant may absorb the heat generated by these components. The heated coolant can then travel to a radiator, where it is cooled down before being recirculated back through the system.

In a number of embodiments, the open loop liquid cooling system may be customizable, allowing users to add, remove, or rearrange components in the loop. The components can include the pump, radiator, reservoir, and cooling blocks. The flexibility may allow the system to be tailored to the specific cooling needs of the devices. In a variety of embodiments, the open loop liquid cooling system can incorporate (hydraulic) solenoid valves at appropriate locations. The solenoid valve may be designed to control the flow of a liquid, such as the coolant in the liquid cooling system. In some embodiments, the solenoid valve can operate by utilizing an electric current to generate a magnetic field, which then may move a plunger inside the valve to open or close the valve. In more embodiments, the solenoid valves may be placed inside the device chassis/enclosure behind the quick disconnect (QD) connectors. In additional embodiments, the solenoid valves can be placed on a coolant distribution manifold, either upstream or downstream of the QD connectors.

In further embodiments, the solenoid valves may be electrically connected to a controller (e.g., a baseboard management controller (BMC)) associated with the device chassis/enclosure. In still more embodiments, the solenoid valves can be electrically connected to the motherboard printed circuit board (PCB). Hereinafter the part of the open loop liquid cooling system associated with and responsible for cooling the components in a chassis may be referred to as a device enclosure-associated liquid cooling system for (associated with) the device chassis. Further, the terms “chassis” and “enclosure” may be used interchangeably hereinafter. Therefore, an open loop cooling system can include multiple device enclosure-associated liquid cooling systems, each of which may be associated with a respective device chassis and can include a respective controller. In still further embodiments, the device enclosure/chassis can include a blade (server) chassis (i.e., a thin, modular case that houses a blade server and can be slid into a rack-mounted blade server enclosure). In still additional embodiments, the device enclosure/chassis may include a rack chassis (i.e., a standardized housing unit that houses various types of hardware and can be mounted directly to a (server) rack). In general, both the rack chassis and the blade chassis can be considered mountable in a rack, either directly or by being slid into a rack-mounted blade server enclosure, respectively.

In some more embodiments, the device enclosure-associated liquid cooling system can include a leak detector. In certain embodiments, by utilizing the leak detector, the controller may detect coolant leaks in the device enclosure-associated liquid cooling system. In yet more embodiments, the leak detector can include one or more liquid pressure sensors. The liquid pressure sensors, placed strategically in the cooling system, may monitor the pressure of the circulating coolant. If a leak occurs, the sensors can detect a drop in pressure and may send a corresponding signal to the controller. In still yet more embodiments, the leak detector may include a leak detection resistance wire. The leak detection resistance wire can be shaped and positioned within the cooling system such that, upon exposure to leaked coolant, the liquid may bridge certain sections of the wire. This action can reduce the total resistance of the wire as measured from its two terminals. The controller may continuously monitor the resistance of the wire, detect the reduction in resistance, and interpret it as a sign of a coolant leak.

In many further embodiments, the leak detector can include a millimeter wave-based (mmWave) leak detector. A mmWave-based leak detector may operate by emitting high-frequency radio waves and analyzing the reflected signals. When a coolant leak occurs, the properties of the reflected waves can change due to the different reflective characteristics of the coolant compared to the normal environment. The leak detector may identify these changes in the reflected signals and interpret them as a leak. The mmWave-based leak detector can further identify the location and impact of the leak by analyzing the reflected waves. In many additional embodiments, the leak detector can include a time-domain reflectometry-based (TDR) leak detector. A TDR-based leak detector may operate by sending a signal along a transmission line and analyzing (the time delay in) the reflected signal. When a coolant leak occurs, it can cause a change in the impedance of the transmission line, which in turn may alter the time domain characteristics of the reflected signal. The TDR-based leak detector can identify these changes and interpret them as a leak. The TDR-based leak detector can further identify the location and impact of the leak by analyzing the time domain characteristics of the reflected signals. In still yet further embodiments, the leak detector may include a vector network analyzer-based (VNA) leak detector. A VNA-based leak detector can operate by sending a range of frequencies through a transmission line within the cooling system and analyzing (the frequency response in) the reflected signals. When a coolant leak occurs, it may alter the impedance of the transmission line, which can change the characteristics of the reflected signals across the frequency range. The VNA-based leak detector can identify these changes and interpret them as a leak. The VNA-based leak detector can further identify the location and impact of the leak by analyzing the frequency response in the reflected signals.

In still yet additional embodiments, upon detecting a leak, the controller can shut down the coolant flow by closing the corresponding solenoid valves in the device enclosure-associated liquid cooling system. In several embodiments, the controller can close the solenoid valves on both the coolant inlet line and the coolant outlet line for the device chassis. In several more embodiments, the controller may close the solenoid valve on the coolant inlet line for the device chassis. Therefore, the shutting down of the coolant flow can be limited to the affected section (e.g., the affected device chassis), preventing a complete system shutdown and localizing the impact of the leak.

In numerous embodiments, the controller may utilize the solenoid valves to control the coolant flow rate based on the thermal load of the devices in the device chassis. In particular, the controller can reduce the coolant flow rate (e.g., by closing down the solenoid valves) in the device enclosure-associated liquid cooling system as the thermal load associated with the device chassis reduces (e.g., during evenings, on weekends, on holidays, etc.), and may increase the coolant flow rate (e.g., by opening up the solenoid valves) in the device enclosure-associated liquid cooling system as the thermal load associated with the device chassis increases. In numerous additional embodiments, the controller can reduce the coolant flow rate in the device enclosure-associated liquid cooling system from the maximum flow rate in response to the thermal load associated with the device chassis being less than a threshold. In further additional embodiments, as the coolant flow rates in one or more device enclosure-associated liquid cooling systems are reduced, the speed of the pump for the whole open loop liquid cooling system may be reduced as well. Accordingly, by adjusting the liquid flow rate in real-time, the system can optimize energy usage and potentially allow for a higher number of devices within a rack.

In some embodiments, upon detecting a coolant leak in a device enclosure-associated liquid cooling system, the corresponding controller may notify a central controller for the rack or the open loop liquid cooling system (or a remote server-based liquid cooling system management service) about the leak. In more embodiments, the central controller or the remote server-based management service can take appropriate actions based on the notification. In additional embodiments, the central controller or the remote server-based management service may shut down the whole open loop liquid cooling system and all the devices in the rack if the leak is determined to be catastrophic. In further embodiments, the central controller or the remote server-based management service can notify the controllers of the device chassis in the rack that are below the device chassis where the coolant leak was first detected, so that the controllers of the device chassis below may take appropriate actions (e.g., shutting down the servers). In still more embodiments, the central controller or the remote server-based management service may notify the controllers of the device chassis in the rack that are above or neighboring to the device chassis where the coolant leak was first detected, so that these controllers of the device chassis may take appropriate actions (e.g., stopping the coolant flow in the respective device enclosure-associated liquid cooling systems ad the detected leak may actually be originating from device chassis that are above or neighboring to the device chassis where the coolant leak was first detected). In still further embodiments, the controller of a device enclosure-associated liquid cooling system can notify the central controller or the remote server-based management service about any detected local condition (such as, but not limited to, a coolant leak or a change in the thermal load), and may take actions in response upon receiving instructions from the central controller or the remote server-based management service where the decision about the actions can actually be made.

Aspects of the present disclosure may be embodied as an apparatus, system, method, or computer program product. Accordingly, aspects of the present disclosure may take the form of an entirely hardware embodiment, an entirely software embodiment (including firmware, resident software, micro-code, or the like) or an embodiment combining software and hardware aspects that may all generally be referred to herein as a “function,” “module,” “apparatus,” or “system.” Furthermore, aspects of the present disclosure may take the form of a computer program product embodied in one or more non-transitory computer-readable storage media storing computer-readable and/or executable program code. Many of the functional units described in this specification have been labeled as functions, in order to emphasize their implementation independence more particularly. For example, a function may be implemented as a hardware circuit comprising custom very large-scale integration (VLSI) circuits or gate arrays, off-the-shelf semiconductors such as logic chips, transistors, or other discrete components. A function may also be implemented in programmable hardware devices such as via field programmable gate arrays, programmable array logic, programmable logic devices, or the like.

Functions may also be implemented at least partially in software for execution by various types of processors. An identified function of executable code may, for instance, comprise one or more physical or logical blocks of computer instructions that may, for instance, be organized as an object, procedure, or function. Nevertheless, the executables of an identified function need not be physically located together but may comprise disparate instructions stored in different locations which, when joined logically together, comprise the function and achieve the stated purpose for the function.

Indeed, a function of executable code may include a single instruction, or many instructions, and may even be distributed over several different code segments, among different programs, across several storage devices, or the like. Where a function or portions of a function are implemented in software, the software portions may be stored on one or more computer-readable and/or executable storage media. Any combination of one or more computer-readable storage media may be utilized. A computer-readable storage medium may include, for example, but not limited to, an electronic, magnetic, optical, electromagnetic, infrared, or semiconductor system, apparatus, or device, or any suitable combination of the foregoing, but would not include propagating signals. In the context of this document, a computer readable and/or executable storage medium may be any tangible and/or non-transitory medium that may contain or store a program for use by or in connection with an instruction execution system, apparatus, processor, or device.

Computer program code for carrying out operations for aspects of the present disclosure may be written in any combination of one or more programming languages, including an object-oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (PCB) or the like. Each of the functions and/or modules described herein, in certain embodiments, may alternatively be embodied by or implemented as a component.

A circuit, as used herein, comprises a set of one or more electrical and/or electronic components providing one or more pathways for electrical current. In certain embodiments, a circuit may include a return pathway for electrical current, so that the circuit is a closed loop. In another embodiment, however, a set of components that does not include a return pathway for electrical current may be referred to as a circuit (e.g., an open loop). For example, an integrated circuit may be referred to as a circuit regardless of whether the integrated circuit is coupled to ground (as a return pathway for electrical current) or not. In various embodiments, a circuit may include a portion of an integrated circuit, an integrated circuit, a set of integrated circuits, a set of non-integrated electrical and/or electrical components with or without integrated circuit devices, or the like. In one embodiment, a circuit may include custom VLSI circuits, gate arrays, logic circuits, or other integrated circuits; off-the-shelf semiconductors such as logic chips, transistors, or other discrete devices; and/or other mechanical or electrical devices. A circuit may also be implemented as a synthesized circuit in a programmable hardware device such as field programmable gate array, programmable array logic, programmable logic device, or the like (e.g., as firmware, a netlist, or the like). A circuit may comprise one or more silicon integrated circuit devices (e.g., chips, die, die planes, packages) or other discrete electrical devices, in electrical communication with one or more other components through electrical lines of a printed circuit board (PCB) or the like. Each of the functions and/or modules described herein, in certain embodiments, may be embodied by or implemented as a circuit.

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to”, unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Further, as used herein, reference to reading, writing, storing, buffering, and/or transferring data can include the entirety of the data, a portion of the data, a set of the data, and/or a subset of the data. Likewise, reference to reading, writing, storing, buffering, and/or transferring non-host data can include the entirety of the non-host data, a portion of the non-host data, a set of the non-host data, and/or a subset of the non-host data.

Lastly, the terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.” An exception to this definition will occur only when a combination of elements, functions, steps, or acts are in some way inherently mutually exclusive.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

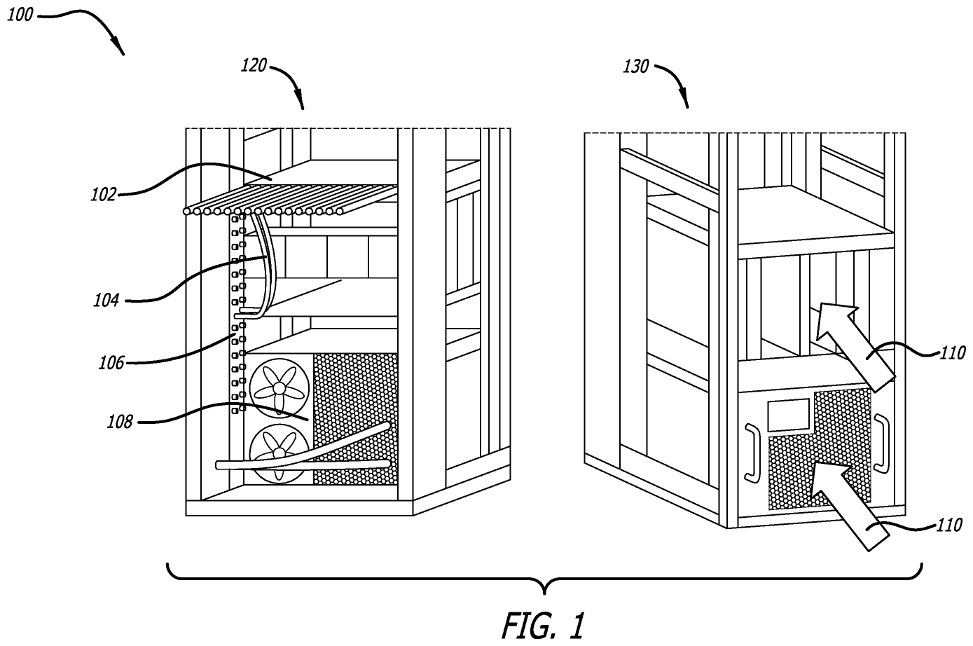

Referring to FIG. 1, a diagram 100 illustrating an open loop liquid cooling system implementation in a rack in accordance with various embodiments of the disclosure is shown. Embodiments shown in FIG. 1 may include two views of a rack: In many embodiments, the diagram 120 can show a first view of a rack, where a liquid distribution unit (LDU) 102, a computing system/server(s) 104, a liquid distribution manifold 106, and a coolant distribution unit (CDU) 108 are installed. In a number of embodiments, the diagram 130 may show second view of the same rack, which shows the opposite side of the rack, and can illustrate the direction of the airflow 110 in relation to the rack and the various components of the open loop liquid cooling system.

In the embodiments shown in the diagram 120, in a variety of embodiments, the LDU 102 may be responsible for distributing the liquid coolant to the various components in the rack. In some embodiments, the computing system/server(s) 104 can represent the high-powered computing devices that are cooled by the liquid coolant. In more embodiments, the manifold 106 may serve as a distribution point for the coolant, directing it to the appropriate components. In additional embodiments, the CDU 108 can be responsible for cooling the heated coolant before it is recirculated back into the system. Further, in the embodiments shown in the diagram 130, the direction of the airflow 110 may be shown. The airflow can aid in the cooling process by helping to dissipate the heat generated by the high-powered computing devices. The airflow may move from the front to the back of the rack, carrying away the heat and helping to maintain a suitable operating temperature for the devices. In further embodiments, the open loop liquid cooling system may be customizable, allowing users to add, remove, or rearrange components in the loop. The components can include the pump, radiator, reservoir, and cooling blocks. The flexibility may allow the system to be tailored to the specific cooling needs of the devices. In still more embodiments, within the computing system/server(s) 104, a device enclosure can be considered to be above another if it is located in a slot higher up (e.g., higher up on the rack, or higher up within a rack-mounted blade server enclosure). Further, device enclosures (especially blade chassis) can be arranged side by side in the same row (e.g., in the rack-mounted blade server enclosure). The side-by-side device enclosures may be considered to be neighboring enclosures at the same horizontal level.

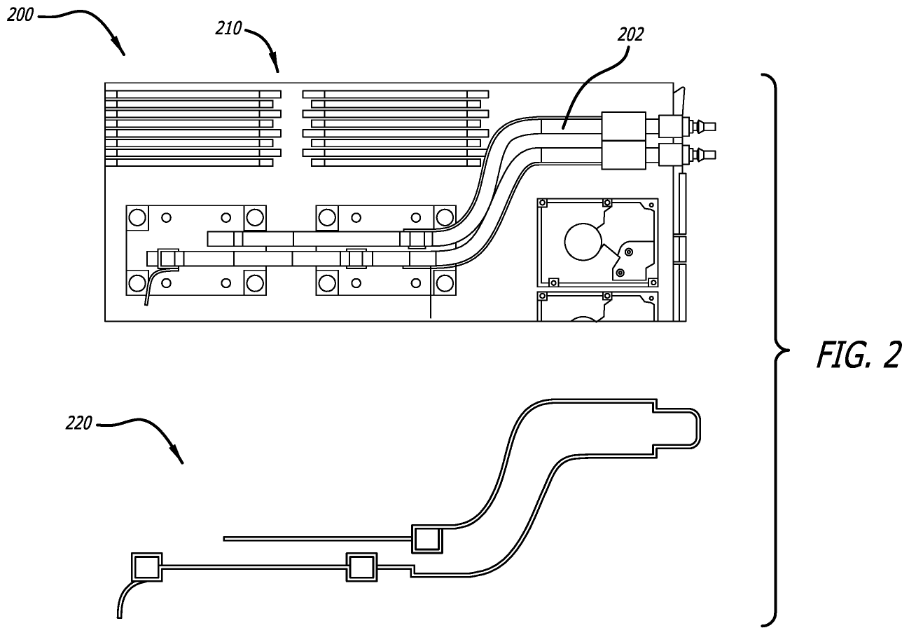

Although a specific embodiment for an open loop liquid cooling system implementation in a rack suitable for carrying out the various steps, processes, methods, and operations described herein is discussed with respect to FIG. 1, any of a variety of systems and/or processes may be utilized in accordance with embodiments of the disclosure. For example, the rack may be configured with multiple LDUs and CDUs to handle higher thermal loads from more powerful computing devices. The elements depicted in FIG. 1 may also be interchangeable with other elements of FIGS. 2-12 as required to realize a particularly desired embodiment.

Referring to FIG. 2, a diagram 200 illustrating single wire leak detection in accordance with various embodiments of the disclosure is shown. In the embodiments shown in FIG. 2, the diagram 210 may show a leak detection wire 202 wrapped around tubes of the device enclosure-associated liquid cooling system in a blade chassis. Further, the diagram 220 can provide an isolated view of the leak detection wire 202. In many embodiments, the leak detection wire 202 may be an exposed metal wire that can come into direct contact with the coolant in the event of a leak.

In a number of embodiments, the leak detection wire 202 can be strategically placed around the tubes of the device enclosure-associated liquid cooling system within the blade chassis. This positioning may allow the leak detection wire 202 to come into contact with coolant that may leak from the tubes. In a variety of embodiments, the leak detection wire 202 can be designed to change its resistance, as measured from its two terminals, when it comes into contact with the coolant. Therefore, the leak detection wire 202 may operate as a coolant leak detector. In particular, upon exposure to leaked coolant, the liquid may bridge certain sections of the leak detection wire 202. This action can reduce the total resistance of the leak detection wire 202 as measured from its two terminals. In some embodiments, the leak detection wire 202 may include additional loops at locations where coolant leak is more likely (e.g., near connectors for the tubes), to improve the ability of the system to promptly detect potential leaks. In more embodiments, the controller may detect the drop in resistance, and can interpret the drop in resistance as a sign of a coolant leak. Accordingly, in additional embodiments, the controller may cause the corresponding solenoid valves to close, in order to completely stop the coolant flow in the device enclosure-associated liquid cooling system for the blade chassis.

Although a specific embodiment for single wire leak detection suitable for carrying out the various steps, processes, methods, and operations described herein is discussed with respect to FIG. 2, any of a variety of systems and/or processes may be utilized in accordance with embodiments of the disclosure. For example, the leak detection wire can be integrated with a temperature sensor to provide additional data about the operating conditions within the device enclosure-associated cooling system. The elements depicted in FIG. 2 may also be interchangeable with other elements of FIGS. 1 and 3-12 as required to realize a particularly desired embodiment.

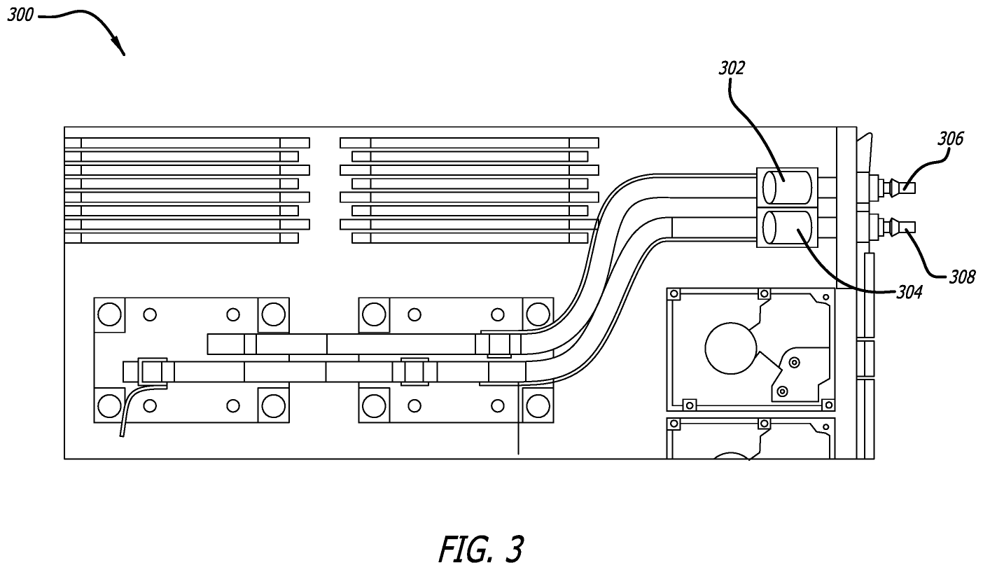

Referring to FIG. 3, a diagram 300 illustrating a top view of the placement of solenoid valves in the device enclosure-associated liquid cooling system within a blade chassis in accordance with various embodiments of the disclosure is shown. In the embodiments shown in FIG. 3, the solenoid valves 302 and 304 may be positioned on the coolant outlet (hot) line and coolant inlet (cold) line, respectively, within the blade chassis. In many embodiments, the solenoid valves 302 and 304 can be utilized to control the flow of coolant within the device enclosure-associated liquid cooling system. In a number of embodiments, a solenoid valve 302 or 304 can operate by utilizing an electric current to generate a magnetic field, which then may move a plunger inside the valve to open or close the valve.

In a variety of embodiments, the solenoid valve 302 may be located on the coolant outlet line, which can carry the heated coolant away from the blade chassis. In some embodiments, the solenoid valve 304 may be positioned on the coolant inlet line, which can bring the cooled coolant into the blade chassis. In more embodiments, both solenoid valves 302 and 304 may be situated within the blade chassis, behind the QD connectors 306 and 308 on their respective lines. In additional embodiments, the solenoid valves 302 and 304 may be electrically connected to the controller associated with the blade chassis. In further embodiments, the solenoid valves 302 and 304 can be electrically connected to the motherboard PCB.

Although a specific embodiment for the placement of solenoid valves in the device enclosure-associated liquid cooling system within a blade chassis suitable for carrying out the various steps, processes, methods, and operations described herein is discussed with respect to FIG. 3, any of a variety of systems and/or processes may be utilized in accordance with embodiments of the disclosure. For instance, additional solenoid valves may be incorporated into the device enclosure-associated liquid cooling system to provide finer control over the coolant flow in different sections of the cooling system. The elements depicted in FIG. 3 may also be interchangeable with other elements of FIGS. 1, 2, and 4-12 as required to realize a particularly desired embodiment.

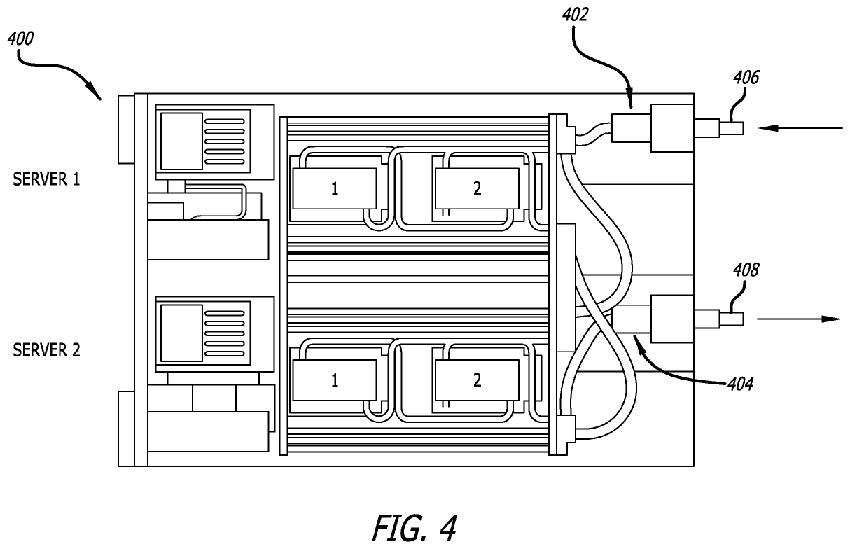

Referring to FIG. 4, a diagram 400 illustrating a top view of the placement of solenoid valves in the device enclosure-associated liquid cooling system within a rack chassis in accordance with various embodiments of the disclosure is shown. In the embodiments shown in FIG. 4, the solenoid valves 402 and 404 may be positioned on the coolant inlet line and coolant outlet line, respectively, within the rack chassis. In many embodiments, the solenoid valve 402 may be located on the coolant inlet line, which can bring the cooled coolant into the rack chassis. In a number of embodiments, the solenoid valve 404 may be positioned on the coolant outlet line, which can carry the heated coolant away from the rack chassis. In a variety of embodiments, both solenoid valves 402 and 404 may be situated within the rack chassis, behind the QD connectors 406 and 408 on their respective lines.

In the embodiments shown in FIG. 4, the rack chassis may include two servers. In some embodiments, each server can feature one or more of driver bays, mezzanine local area network (LAN)-on-motherboard generation 2 (ML2) slots, serial advanced technology attachment (SATA) connectors, non-volatile memory express (NVMe) connectors, M.2 adapters, (internal) peripheral component interconnect express (PCIe) slots, a trusted computing module (TCM) chip/socket, dual in-line memory module (DIMM) slots, a light path diagnostics button, and/or central processing units (CPUs) with liquid-cooled cold plates. In more embodiments, tubes of the device enclosure-associated liquid cooling system may extend to each of the major components, ensuring efficient heat removal.

Although a specific embodiment for the placement of solenoid valves in the device enclosure-associated liquid cooling system within a rack chassis suitable for carrying out the various steps, processes, methods, and operations described herein is discussed with respect to FIG. 4, any of a variety of systems and/or processes may be utilized in accordance with embodiments of the disclosure. For example, the system can be configured with additional solenoid valves or cooling tubes to accommodate a rack chassis with more servers or different component configurations. Further, the solenoid valves may be implemented in switches and other form factors as well. The elements depicted in FIG. 4 may also be interchangeable with other elements of FIGS. 1-3 and 5-12 as required to realize a particularly desired embodiment.

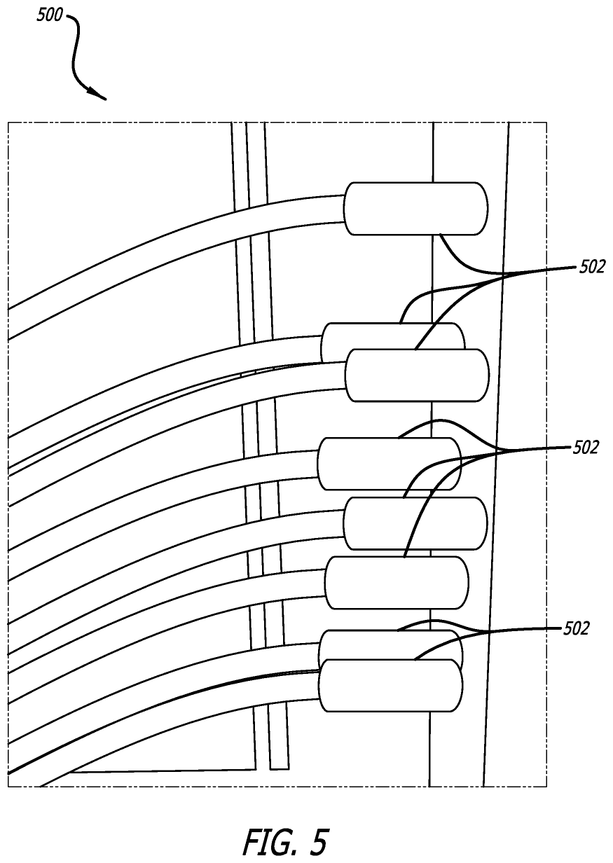

Referring to FIG. 5, a diagram 500 illustrating the placement of solenoid valves on the coolant lines of a coolant distribution manifold in accordance with various embodiments of the disclosure is shown. In the embodiments depicted in FIG. 5, the solenoid valves 502 may be positioned on the coolant lines of a coolant distribution manifold, located outside of the device chassis. In particular, in many embodiments, the solenoid valves 502 can be positioned next to the QD connectors on the coolant lines (e.g., either upstream or downstream of the QD connectors). In a number of embodiments, the solenoid valves 502 may be utilized to control the flow of coolant within the various device enclosure-associated liquid cooling systems. The coolant distribution manifold can serve as a distribution point for the coolant, directing it to the appropriate components within the device chassis. The placement of the solenoid valves 502 outside of the device chassis may allow for easier access for maintenance or system upgrades.

Although a specific embodiment for the placement of solenoid valves on the coolant lines of a coolant distribution manifold suitable for carrying out the various steps, processes, methods, and operations described herein is discussed with respect to FIG. 5, any of a variety of systems and/or processes may be utilized in accordance with embodiments of the disclosure. For example, the system may be configured with additional solenoid valves on the coolant distribution manifold to provide finer control over the coolant distribution to different sections of the open loop liquid cooling system. The elements depicted in FIG. 5 may also be interchangeable with other elements of FIGS. 1-4 and 6-12 as required to realize a particularly desired embodiment.

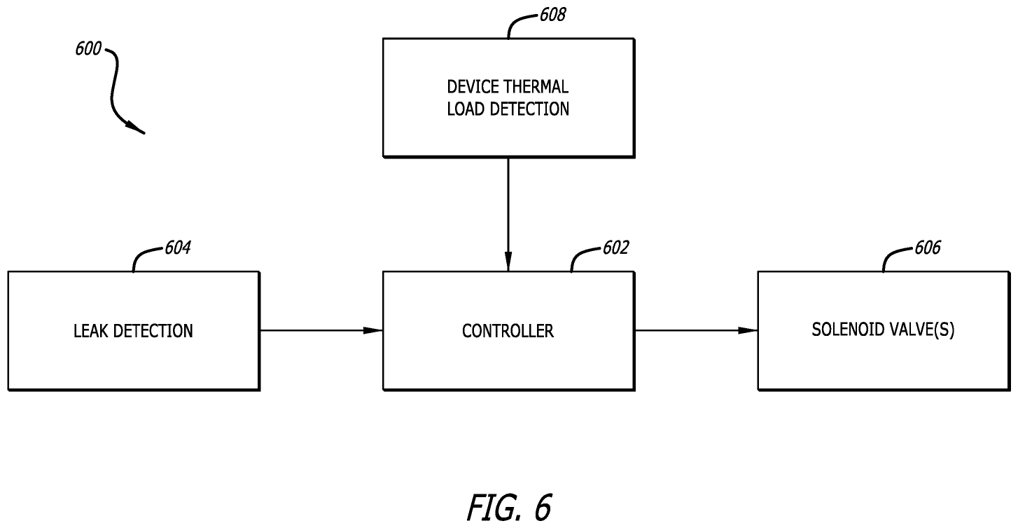

Referring to FIG. 6, a diagram 600 illustrating the interaction between various components in a device enclosure-associated liquid cooling system in accordance with various embodiments of the disclosure is shown. In many embodiments, the controller 602 (e.g., a BMC) may serve as the central control unit, managing and coordinating the operations of the other components of the device enclosure-associated liquid cooling system. In a number of embodiments, the controller 602 can receive input from the leak detection module 604 and/or the device thermal load detection module 608, and may control the operation of the solenoid valve(s) 606 based on the input.

In a variety of embodiments, the leak detection module 604 may monitor the device enclosure-associated liquid cooling system for potential coolant leaks. In some embodiments, the leak detector can include one or more liquid pressure sensors. In more embodiments, the leak detector may include a leak detection resistance wire. In additional embodiments, the leak detector can include a millimeter wave-based (mmWave) leak detector. In further embodiments, the leak detector can include a TDR-based leak detector. In still more embodiments, the leak detector may include a VNA-based leak detector. If a coolant leak is present, the controller 602 can detect the leak based on the input from the leak detection module 604. In still further embodiments, the controller 602 may then take appropriate action, such as shutting down the coolant flow by closing the solenoid valve(s) 606. In still additional embodiments, the controller can close the solenoid valves on both the coolant inlet line and the coolant outlet line for the device chassis. In some more embodiments, the controller may close the solenoid valve on the coolant inlet line for the device chassis. Therefore, the shutting down of the coolant flow can be limited to the affected section (e.g., the affected device chassis), preventing a complete system shutdown and localizing the impact of the leak.

In certain embodiments, the device thermal load detection module 608 may monitor the thermal load of the devices in the device chassis. In yet more embodiments, the device thermal load detection module 608 can provide the device thermal data to the controller 602. In still yet more embodiments, the controller 602 may then adjust the coolant flow rate by controlling the solenoid valve(s) 606. In particular, the controller can reduce the coolant flow rate (e.g., by closing down the solenoid valves) in the device enclosure-associated liquid cooling system as the thermal load associated with the device chassis reduces, and may increase the coolant flow rate (e.g., by opening up the solenoid valves) in the device enclosure-associated liquid cooling system as the thermal load associated with the device chassis increases. In many further embodiments, the controller can reduce the coolant flow rate in the device enclosure-associated liquid cooling system from the maximum flow rate in response to the thermal load associated with the device chassis being less than a threshold. In many additional embodiments, as the coolant flow rates in one or more device enclosure-associated liquid cooling systems are reduced, the speed of the pump for the whole open loop liquid cooling system may be reduced as well. As a result, energy usage may be better optimized, and a higher number of devices can potentially be accommodated within a rack. This can create, in certain embodiments, a closed loop system where the temperature monitoring in response to the change of the solenoid valve(s) can be utilized as input to the device thermal load detection 608.

Although a specific embodiment for the interaction between various components in a device enclosure-associated liquid cooling system suitable for carrying out the various steps, processes, methods, and operations described herein is discussed with respect to FIG. 6, any of a variety of systems and/or processes may be utilized in accordance with embodiments of the disclosure. For example, the system can be configured with additional sensors or modules to provide more detailed monitoring and control capabilities. The elements depicted in FIG. 6 may also be interchangeable with other elements of FIGS. 1-5 and 7-12 as required to realize a particularly desired embodiment.

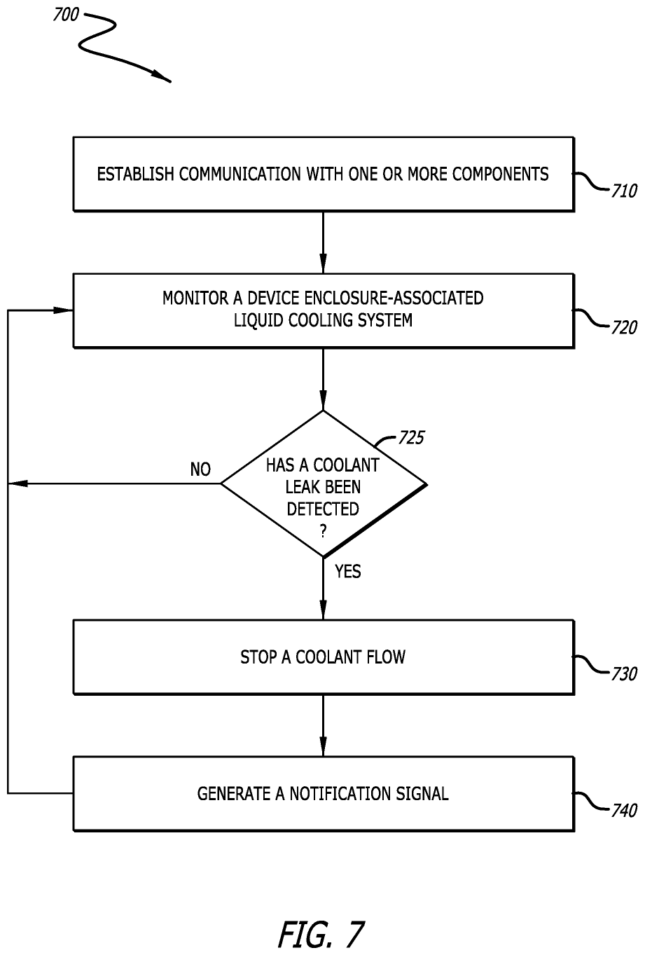

Referring to FIG. 7, a flowchart showing a process 700 for managing a device enclosure-associated liquid cooling system in accordance with various embodiments of the disclosure is shown. In many embodiments, the process 700 may establish communication with components (block 710). In a number of embodiments, this can involve the controller initializing a connection with various components of the device enclosure-associated liquid cooling system, such as, but not limited to, the solenoid valves, the leak detection module, and the device thermal load detection module. The communication may allow the controller to monitor and control the operation of these components.

In a variety of embodiments, the process 700 may monitor the device enclosure-associated liquid cooling system (block 720). In some embodiments, the monitoring can involve continuously checking the output of the leak detection module and/or the device thermal load detection module. The monitoring may allow the system to quickly respond to any changes in the operating conditions.

In more embodiments, the process 700 can determine if a coolant leak has been detected (block 725). In additional embodiments, this can involve the controller monitoring the output of the leak detection module. In further embodiments, the leak detection module may include a leak detection wire. The coolant leak can change the resistance of the leak detection wire when the leak detection wire comes into contact with the coolant. In particular, the leaked coolant may bridge certain sections of the wire and as a result, cause the resistance of the leak detection wire, as measured from the two terminals of the wire, to drop. In still more embodiments, this change in resistance can be detected and interpreted by the controller as a sign of a coolant leak. In still further embodiments, in response to a coolant leak being detected, the process 700 can stop the coolant flow. However, in still additional embodiments, when a coolant leak is not detected, the process 700 can return to monitoring the device enclosure-associated liquid cooling system.

In some more embodiments, in response to a coolant leak being detected, the process 700 can stop the coolant flow (block 730). In certain embodiments, this can involve the controller generating appropriate electrical outputs to cause the solenoid valves to close, thereby stopping the flow of coolant within the device enclosure-associated liquid cooling system. This action may help to minimize the impact of the leak and prevent further damage to the devices.

In yet more embodiments, the process 700 can generate a notification signal (block 740). In still yet more embodiments, this may involve sending a signal to an external (off-device enclosure) controller, such as, but not limited to, a central controller associated with the rack or the open loop liquid cooling system, or a remote server-based management service. The notification signal can notify the external controller of the detected leak.

Although a specific embodiment for managing a device enclosure-associated liquid cooling system suitable for carrying out the various steps, processes, methods, and operations described herein is discussed with respect to FIG. 7, any of a variety of systems and/or processes may be utilized in accordance with embodiments of the disclosure. For example, the device enclosure-associated liquid cooling system may incorporate a predictive maintenance module that utilizes machine learning processes to analyze historical data and predict when a coolant leak is likely to occur, allowing for proactive maintenance and potentially reducing system downtime. The elements depicted in FIG. 7 may also be interchangeable with other elements of FIGS. 1-6 and 8-12 as required to realize a particularly desired embodiment.

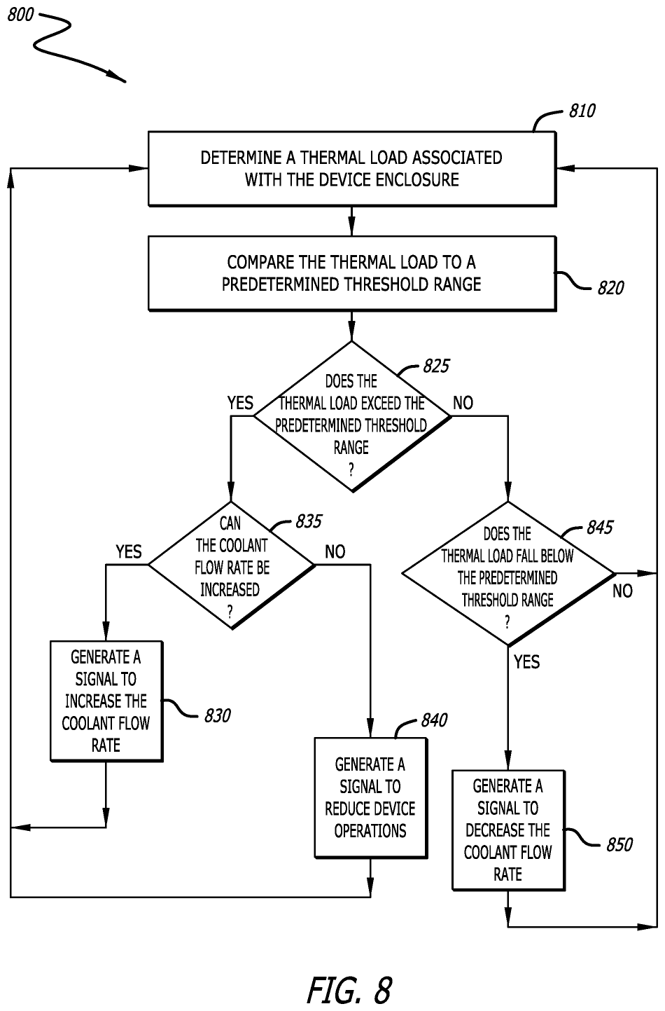

Referring to FIG. 8, a flowchart showing a process 800 for managing a device enclosure-associated liquid cooling system based on thermal load in accordance with various embodiments of the disclosure is shown. In many embodiments, the process 800 may determine a thermal load associated with the device enclosure (block 810). In a number of embodiments, this can involve monitoring the output of the device thermal load detection module. In a variety of embodiments, the thermal load detection module may measure the amount of heat being generated by the devices in the enclosure, and can report the measurement results to the controller.

In some embodiments, the process 800 can compare the thermal load to a predetermined threshold range (block 820). In more embodiments, this may involve comparing the measured thermal load to a predetermined threshold value or range of values. In additional embodiments, the coolant flow rates and thermal load values or value ranges can be associated based on a predetermined relationship. In general, the coolant flow rate and the thermal load value or value range may be positively correlated. Accordingly, in further embodiments, the predetermined threshold value or range of values can correspond to the thermal load value or the range of thermal load values corresponding to the present coolant flow rate.

In still more embodiments, the process 800 can determine if the thermal load exceeds the predetermined threshold range (block 825). In still further embodiments, in response to the thermal load exceeding the threshold range, the process 800 may determine if the coolant flow rate can be increased. However, in still additional embodiments, if the thermal load does not exceed the predetermined threshold range, the process 800 can determine if the thermal load falls below the predetermined threshold range.

In some more embodiments, in response to the thermal load exceeding the threshold range, the process 800 may determine if the coolant flow rate can be increased (block 835). In certain embodiments, in response to determining that the coolant flow rate can be increased, the process 800 can generate a signal to increase the coolant flow rate. However, in yet more embodiments, if it is determined that the coolant flow rate cannot be increased (e.g., the coolant flow rate is already at its maximum), the process 800 can generate a signal to reduce device operations.

In still yet more embodiments, in response to determining that the coolant flow rate can be increased, the process 800 can generate a signal to increase the coolant flow rate (block 830). In many further embodiments, this may involve sending a signal to the solenoid valves to cause the solenoid valves to open further, thereby increasing the flow of coolant within the liquid cooling system. In many additional embodiments, the coolant flow rate can be increased to a new flow rate based on the present thermal load and the predetermined relationship that associates the coolant flow rates and thermal load values or value ranges. In still yet further embodiments, the increase in the coolant flow rate can also be communicated to an external controller, such as, but not limited to, a central controller associated with the rack or the open loop liquid cooling system, or a remote server-based management service, to keep the external controller informed about the changes in the operation of the device enclosure-associated liquid cooling system.

However, in still yet additional embodiments, if the coolant flow rate cannot be increased, the process 800 can generate a signal to reduce device operations (block 840). The coolant flow rate may not be able to be further increased because the coolant flow rate is already at its maximum. In several embodiments, reducing device operations may involve throttling the operation of the devices within the enclosure or even turning the devices off to reduce the thermal load.

In several more embodiments, the process 800 can determine if the thermal load falls below the predetermined threshold range (block 845). In numerous embodiments, in response to the thermal load falling below the threshold range, the process 800 can generate a signal to decrease the coolant flow rate. However, in numerous additional embodiments, if the thermal load does not fall below the predetermined threshold range, the process 800 may return to determining a thermal load associated with the device enclosure.

In further additional embodiments, in response to the thermal load falling below the threshold range, the process 800 can generate a signal to decrease the coolant flow rate (block 850). In some embodiments, this may involve sending a signal to the solenoid valves to cause the solenoid valves to partially close (or close down further), thereby reducing the flow of coolant within the system. In more embodiments, the coolant flow rate can be decreased to a new flow rate based on the present thermal load and the predetermined relationship that associates the coolant flow rates and thermal load values or value ranges. In additional embodiments, the new coolant flow rate after the decrease may be zero. In other words, the coolant flow can be stopped if the devices in the enclosure are generating no or negligible heat. In further embodiments, the decrease in the coolant flow rate can also be communicated to an external controller, such as, but not limited to, a central controller associated with the rack or the open loop liquid cooling system, or a remote server-based management service, to keep the external controller informed about the changes in the operation of the device enclosure-associated liquid cooling system.

Although a specific embodiment for managing a device enclosure-associated liquid cooling system based on thermal load suitable for carrying out the various steps, processes, methods, and operations described herein is discussed with respect to FIG. 8, any of a variety of systems and/or processes may be utilized in accordance with embodiments of the disclosure. For example, the system can be configured with dynamic thresholds or threshold ranges that adjust based on factors such as, but not limited to, the time of day, the expected workload, or the ambient temperature. The elements depicted in FIG. 8 may also be interchangeable with other elements of FIGS. 1-7 and 9-12 as required to realize a particularly desired embodiment.

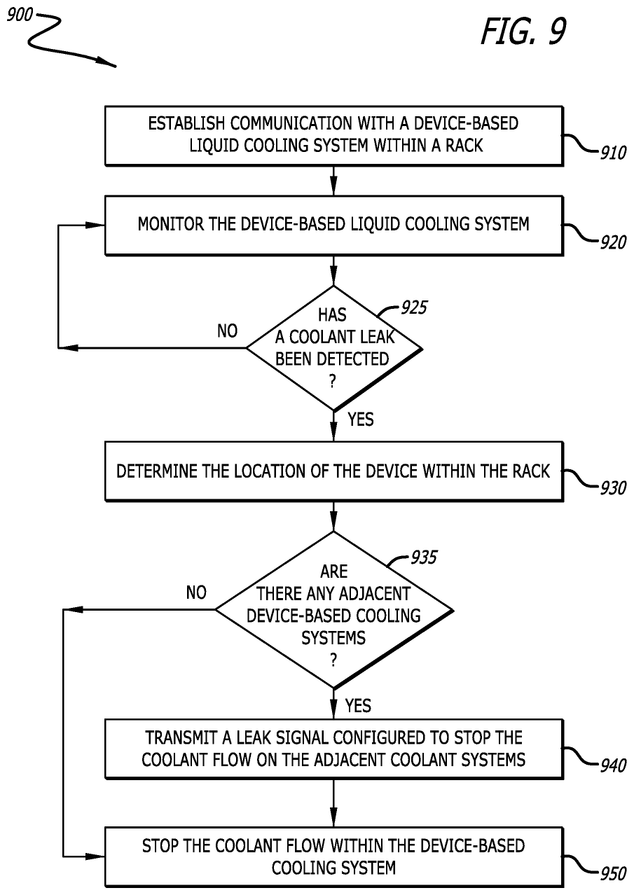

Referring to FIG. 9, a flowchart showing a process 900 for managing a device enclosure-associated liquid cooling system within a rack by an external controller in accordance with various embodiments of the disclosure is shown. In many embodiments, the process 900 may establish communication with a device enclosure-associated liquid cooling system within a server rack (block 910). In a number of embodiments, this can involve an external controller initializing a connection with the device enclosure-associated liquid cooling system, enabling the monitoring and control of its operation. In a variety of embodiments, the external controller may be a central controller associated with the server rack or the open loop liquid cooling system. In some embodiments, the external controller can include a remote server-based management service.

In more embodiments, the process 900 may monitor the device enclosure-associated liquid cooling system (block 920). In additional embodiments, this can involve continuously communicating with a device enclosure-associated controller to check the output of the leak detection module and/or the device thermal load detection module in the device enclosure-associated liquid cooling system. The monitoring may allow the external controller to quickly respond to any changes in the operating conditions.

In further embodiments, the process 900 can determine if a coolant leak has been detected (block 925). In still more embodiments, in response to a coolant leak being detected, the process 900 can determine the location of the device enclosure within the rack. However, in still further embodiments, if a coolant leak has not been detected, the process 900 may return to monitoring the device enclosure-associated liquid cooling system.

In still additional embodiments, in response to a coolant leak being detected, the process 900 can determine the location of the device enclosure within the rack (block 930). In some more embodiments, determining the location of the device enclosure within the rack may involve using data from a rack management module or a similar system that keeps track of the physical layout of the server rack. This data can be crucial in understanding the potential impact of a coolant leak, as it can help identify which other device enclosures might be the actual source of the coolant leak or might be at risk due to their proximity to the leak.

In certain embodiments, the process 900 can determine if there are any adjacent device enclosure-associated liquid cooling systems by the detected leak (block 935). In some embodiments, there may be multiple systems within a shared rack. Detected leaks may, in certain cases, be sourced from other devices and liquid cooling systems within the rack. If the leak is associated with an adjacent device enclosure-associated liquid cooling systems, the process 900 can attempt to turn stop the leak. As those skilled in the art will recognize, the term “adjacent” may include any device enclosure-associated liquid cooling systems that are within range of a leak. In other words, if a device enclosure-associated liquid cooling system leak can reach to another device enclosure-associated liquid cooling system can be “adjacent”. In some embodiments, that may be any systems above or horizontal to a device enclosure-associated liquid cooling system.

In many further embodiments, in response to there being additional device enclosure-associated liquid cooling systems adjacent the detected leak, the process 900 can transmit a leak signal configured to stop the coolant flow on the above liquid cooling systems (block 940). In many additional embodiments, transmitting a leak signal configured to stop the coolant flow on the above liquid cooling systems may involve sending an instruction to the controller at each of the above enclosure-based liquid cooling systems. The instruction can prompt those enclosure-associated controllers to actuate the solenoid valves within their respective enclosure-associated liquid cooling systems, thereby stopping the coolant flow. The action may be taken because the detected leak may actually be originating from a system located above and trickling down. Therefore, stopping the coolant flow in the above systems can help isolate the source of the leak and prevent further coolant loss.

In several more embodiments, in response to there being adjacent device enclosures with liquid cooling systems, the process 900 can transmit a leak signal configured to stop the coolant flow on the neighboring liquid cooling systems (block 950). In numerous embodiments, neighboring systems on the same horizontal level may refer to other device enclosures that are positioned side by side in the same horizontal row. In numerous additional embodiments, transmitting a leak signal configured to stop the coolant flow on the adjacent liquid cooling systems may involve sending an instruction to the controller at each of the neighboring enclosure-based liquid cooling systems. The instruction can prompt those controllers to actuate the solenoid valves within their respective systems, thereby stopping the coolant flow. This action may be taken because the detected leak may actually be originating from neighboring systems on the same horizontal level. Therefore, stopping the coolant flow in these systems can help prevent the leak from affecting a wider area within the rack.

In further additional embodiments, the process 900 can stop the coolant flow within the device enclosure-associated liquid cooling system (block 960). This could involve sending a signal to the solenoid valves to close, thereby stopping the flow of coolant within the system. In some embodiments, stopping the coolant flow within the device enclosure-associated liquid cooling system may involve sending an instruction to the controller associated with the enclosure-associated liquid cooling system where the leak was detected. The instruction can prompt the controller to actuate the solenoid valves within its system, thereby stopping the coolant flow.

Although a specific embodiment for managing a device enclosure-associated liquid cooling system within a rack by an external controller suitable for carrying out the various steps, processes, methods, and operations described herein is discussed with respect to FIG. 9, any of a variety of systems and/or processes may be utilized in accordance with embodiments of the disclosure. For example, the system can be configured with an automated leak response protocol that, upon receiving a leak signal, not only stops the coolant flow but also initiates a series of diagnostic tests to identify the source of the leak and assess the extent of any damage. The elements depicted in FIG. 9 may also be interchangeable with other elements of FIGS. 1-8 and 10-12 as required to realize a particularly desired embodiment.

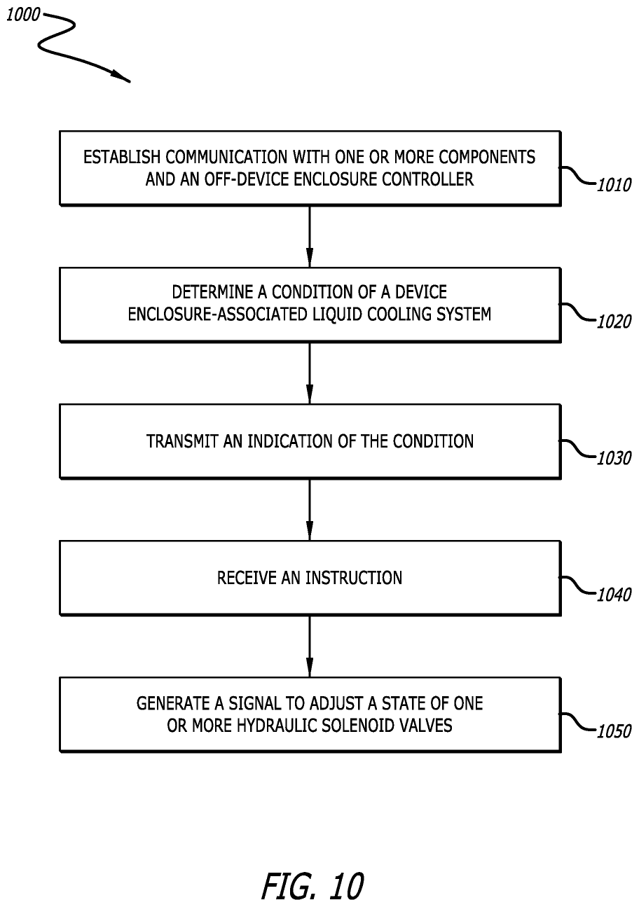

Referring to FIG. 10, a flowchart showing a process 1000 for managing a device enclosure-associated liquid cooling system in accordance with various embodiments of the disclosure is shown. In many embodiments, the process 1000 may establish communication with one or more components and an off-device enclosure controller (block 1010). In a number of embodiments, this can involve initializing a connection with various components of the device enclosure-associated liquid cooling system, such as, but not limited to, the solenoid valves, leak detection module, and device thermal load detection module, as well as an external controller that oversees the operation of the cooling system. In a variety of embodiments, the off-device enclosure controller may be a central controller associated with the rack or the open loop liquid cooling system. In some embodiments, the off-device enclosure controller can be a remote server-based management service.

In more embodiments, the process 1000 may determine a condition of a device enclosure-associated liquid cooling system (block 1020). In additional embodiments, this can involve monitoring the output of the leak detection module and/or the device thermal load detection module, allowing the system to quickly respond to any changes in the operating conditions. In further embodiments, the condition may include a coolant leak. In still more embodiments, the condition can include a change in the thermal load associated with the device enclosure.

In still further embodiments, the process 1000 can transmit an indication of the condition (block 1030). In still additional embodiments, this may involve sending a signal to the off-device enclosure controller to provide the up-to-date data about the condition of the device enclosure-associated liquid cooling system. In some more embodiments, transmitting the indication of the condition can involve encoding the condition data in a format or protocol that is compatible with the off-device enclosure controller.

In certain embodiments, the process 1000 can receive an instruction (block 1040). In yet more embodiments, this may involve receiving a command from the off-device enclosure controller, based on the analysis by the off-device enclosure controller of the condition indication and potentially other factors such as, but not limited to, the overall cooling needs of the rack or the status of other parts of the open loop cooling system. In still yet more embodiments, receiving the instruction can involve decoding or interpreting the instruction data received from the off-device enclosure controller.

In many further embodiments, the process 1000 can generate a signal to adjust a state of one or more hydraulic solenoid valves (block 1050). In many additional embodiments, the signal may be generated based on the instruction received from the off-device enclosure controller. The signal can cause the solenoid valves to open or close, thereby adjusting the flow of coolant within the device enclosure-associated liquid cooling system in accordance with the instruction received from the off-device enclosure controller. In still yet further embodiments, if the condition includes a coolant leak, the signal may cause the solenoid valves to completely close to stop the coolant flow. In still yet additional embodiments, if the condition includes a change in the thermal load associated with the device enclosure, the signal may cause the solenoid valves to further open or close to adjust the coolant flow rate based on a predetermined positive correlation between the coolant flow rates and the thermal load values or value ranges.

Although a specific embodiment for managing a device enclosure-associated liquid cooling system suitable for carrying out the various steps, processes, methods, and operations described herein is discussed with respect to FIG. 10, any of a variety of systems and/or processes may be utilized in accordance with embodiments of the disclosure. For example, the system may be configured with a fail-safe mechanism that automatically shuts down the device enclosure-based liquid cooling system if communication with the off-device enclosure controller is lost. The elements depicted in FIG. 10 may also be interchangeable with other elements of FIGS. 1-9, 11, and 12 as required to realize a particularly desired embodiment.

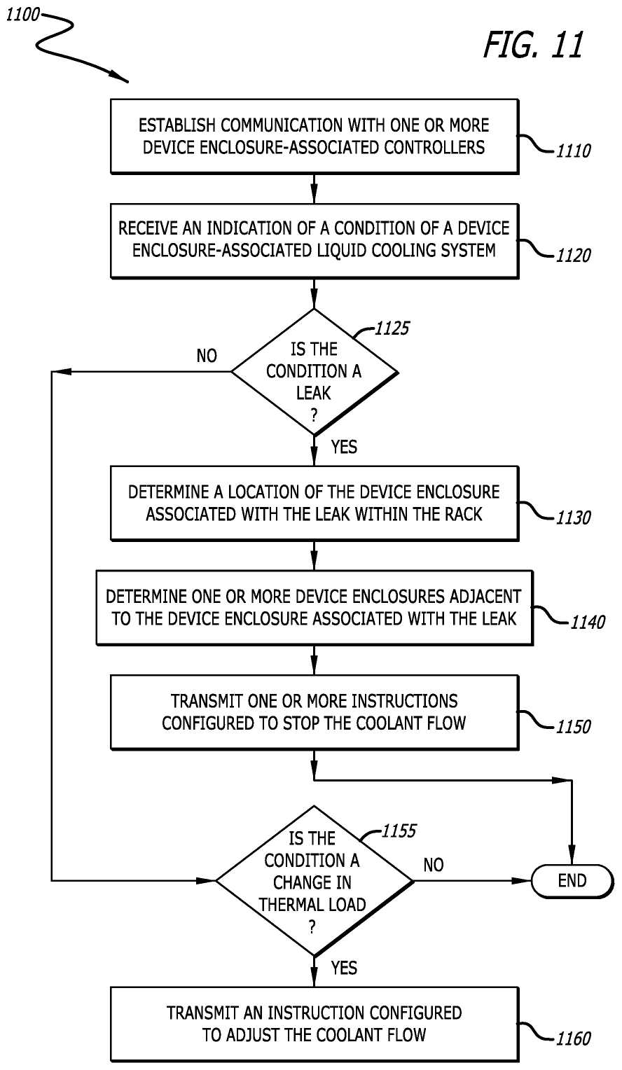

Referring to FIG. 11, a flowchart showing a process 1100 for managing a device enclosure-associated liquid cooling system in accordance with various embodiments of the disclosure is shown. In many embodiments, the process 1100 may establish communication with one or more device enclosure-associated controllers (block 1110). In a number of embodiments, this can involve an off-device enclosure controller initializing a connection with the controllers associated with various device enclosure-associated liquid cooling systems within a rack. In a variety of embodiments, the off-device enclosure controller may be a central controller associated with the rack or the open loop liquid cooling system. In some embodiments, the off-device enclosure controller can be a remote server-based management service.

In more embodiments, the process 1100 may receive an indication of a condition of a device enclosure-associated liquid cooling system (block 1120). In additional embodiments, this can involve receiving data from a device enclosure-associated controller about the current operating conditions of the corresponding device enclosure-associated liquid cooling system. In further embodiments, the condition may include a coolant leak. In still more embodiments, the condition can include a change in the thermal load associated with the device enclosure.

In still further embodiments, the process 1100 can determine if the condition is a coolant leak (block 1125). In still additional embodiments, in response to the condition being a leak, the process 1100 can determine the location of the device enclosure associated with the leak within the rack. However, in some more embodiments, if the condition is not a coolant leak, the process 1100 may determine if the condition is a change in the thermal load associated with the device enclosure.

In certain embodiments, in response to the condition being a leak, the process 1100 can determine the location of the device enclosure associated with the leak within the rack (block 1130). In yet more embodiments, this may involve using data from a rack management module or a similar system that keeps track of the physical layout of the server rack. Cross-referencing the received leak indication with the rack layout data can help pinpoint the exact location of the device enclosure associated with the coolant leak within the potentially complex arrangement of multiple rack chassis and/or blade chassis in the server rack.

In still yet more embodiments, the process 1100 can determine one or more device enclosures are adjacent to the device enclosure associated with the leak (block 1140). In many further embodiments, the determination may be based on the determined location of the device enclosure associated with the coolant leak. In many additional embodiments, this can involve identifying other device enclosures that are positioned above or side by side with the device enclosure associated with the detected coolant leak. In still yet further embodiments, just the device enclosures including device enclosure-associated liquid cooling systems may be identified at block 1140.

In still yet additional embodiments, the process 1100 can transmit one or more instructions configured to stop the coolant flow (block 1150). In several embodiments, this may involve sending commands to the controllers associated with the identified device enclosures, instructing them to actuate the solenoid valves within their respective device enclosure-associated liquid cooling systems to stop the coolant flow. The action may be taken because the detected leak may actually be originating from a system located above and trickling down, or from neighboring systems on the same horizontal level. Therefore, stopping the coolant flow in these systems can help isolate the source of the leak and prevent further coolant loss.

In several more embodiments, if the condition is not a coolant leak, the process 1100 may determine if the condition is a change in the thermal load associated with the device enclosure (block 1155). In numerous embodiments, in response to the condition being a change in the thermal load associated with the device enclosure, the process 1100 can transmit an instruction configured to adjust the coolant flow (block 1160). In numerous additional embodiments, this may involve sending a command to the relevant device enclosure-associated controller, instructing it to adjust the coolant flow rate in response to the change in thermal load by sending an appropriate signal to the solenoid valves in the relevant device enclosure-associated liquid cooling system. In particular, the signal can cause the solenoid valves to further open or close to adjust the coolant flow rate based on a predetermined positive correlation between the coolant flow rates and the thermal load values or value ranges.

Although a specific embodiment for managing a device enclosure-associated liquid cooling system suitable for carrying out the various steps, processes, methods, and operations described herein is discussed with respect to FIG. 11, any of a variety of systems and/or processes may be utilized in accordance with embodiments of the disclosure. For example, the system could be configured with a predictive maintenance module that uses machine learning algorithms to analyze historical data and predict when a coolant leak is likely to occur, allowing for proactive maintenance and potentially reducing system downtime. The elements depicted in FIG. 11 may also be interchangeable with other elements of FIGS. 1-10 and 12 as required to realize a particularly desired embodiment.

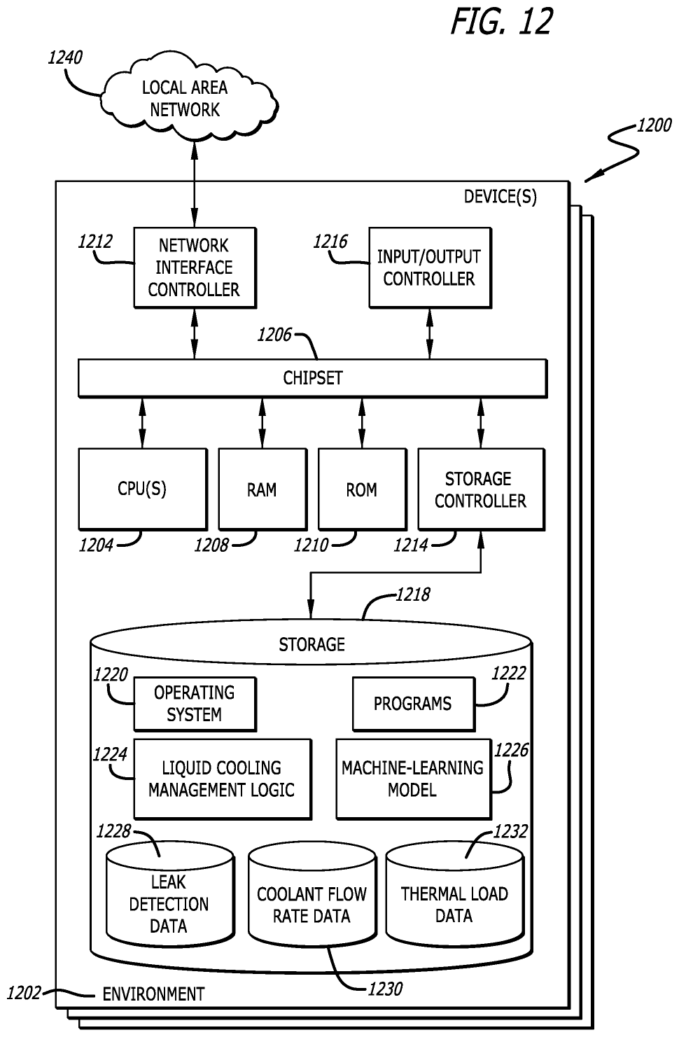

Referring to FIG. 12, a conceptual block diagram for one or more devices 1200 capable of executing components and logic for implementing the functionality and embodiments described above is shown. The embodiment of the conceptual block diagram depicted in FIG. 12 can illustrate a conventional server computer, workstation, desktop computer, laptop, tablet, network appliance, e-reader, smartphone, or other computing device, and can be utilized to execute any of the application and/or logic components presented herein. The device 1200 may, in some examples, correspond to physical devices or to virtual resources described herein.

In many embodiments, the device 1200 may include an environment 1202 such as a baseboard or “motherboard,” in physical embodiments that can be configured as a printed circuit board with a multitude of components or devices connected by way of a system bus or other electrical communication paths. Conceptually, in virtualized embodiments, the environment 1202 may be a virtual environment that encompasses and executes the remaining components and resources of the device 1200. In more embodiments, one or more processors 1204, such as, but not limited to, central processing units (“CPUs”) can be configured to operate in conjunction with a chipset 1206. The processor(s) 1204 can be standard programmable CPUs that perform arithmetic and logical operations necessary for the operation of the device 1200.

In additional embodiments, the processor(s) 1204 can perform one or more operations by transitioning from one discrete, physical state to the next through the manipulation of switching elements that differentiate between and change these states. Switching elements generally include electronic circuits that maintain one of two binary states, such as flip-flops, and electronic circuits that provide an output state based on the logical combination of the states of one or more other switching elements, such as logic gates. These basic switching elements can be combined to create more complex logic circuits, including registers, adders-subtractors, arithmetic logic units, floating-point units, and the like.

In certain embodiments, the chipset 1206 may provide an interface between the processor(s) 1204 and the remainder of the components and devices within the environment 1202. The chipset 1206 can provide an interface to a random-access memory (“RAM”) 1208, which can be used as the main memory in the device 1200 in some embodiments. The chipset 1206 can further be configured to provide an interface to a computer-readable storage medium such as a read-only memory (“ROM”) 1210 or non-volatile RAM (“NVRAM”) for storing basic routines that can help with various tasks such as, but not limited to, starting up the device 1200 and/or transferring information between the various components and devices. The ROM 1210 or NVRAM can also store other application components necessary for the operation of the device 1200 in accordance with various embodiments described herein.

Different embodiments of the device 1200 can be configured to operate in a networked environment using logical connections to remote computing devices and computer systems through a network, such as the network 1240. The chipset 1206 can include functionality for providing network connectivity through a network interface card (“NIC”) 1212, which may comprise a gigabit Ethernet adapter or similar component. The NIC 1212 can be capable of connecting the device 1200 to other devices over the network 1240. It is contemplated that multiple NICs 1212 may be present in the device 1200, connecting the device to other types of networks and remote systems.

In further embodiments, the device 1200 can be connected to a storage 1218 that provides non-volatile storage for data accessible by the device 1200. The storage 1218 can, for example, store an operating system 1220, applications 1222, leak detection data 1228, coolant flow rate data 1230, and thermal load data 1232, which are described in greater detail below. The storage 1218 can be connected to the environment 1202 through a storage controller 1214 connected to the chipset 1206. In certain embodiments, the storage 1218 can consist of one or more physical storage units. The storage controller 1214 can interface with the physical storage units through a serial attached SCSI (“SAS”) interface, a serial advanced technology attachment (“SATA”) interface, a fiber channel (“FC”) interface, or other type of interface for physically connecting and transferring data between computers and physical storage units.

The device 1200 can store data within the storage 1218 by transforming the physical state of the physical storage units to reflect the information being stored. The specific transformation of physical state can depend on various factors. Examples of such factors can include, but are not limited to, the technology used to implement the physical storage units, whether the storage 1218 is characterized as primary or secondary storage, and the like.

For example, the device 1200 can store information within the storage 1218 by issuing instructions through the storage controller 1214 to alter the magnetic characteristics of a particular location within a magnetic disk drive unit, the reflective or refractive characteristics of a particular location in an optical storage unit, or the electrical characteristics of a particular capacitor, transistor, or other discrete component in a solid-state storage unit, or the like. Other transformations of physical media are possible without departing from the scope and spirit of the present description, with the foregoing examples provided only to facilitate this description. The device 1200 can further read or access information from the storage 1218 by detecting the physical states or characteristics of one or more particular locations within the physical storage units.

In addition to the storage 1218 described above, the device 1200 can have access to other computer-readable storage media to store and retrieve information, such as program modules, data structures, or other data. It should be appreciated by those skilled in the art that computer-readable storage media is any available media that provides for the non-transitory storage of data and that can be accessed by the device 1200. In some examples, the operations performed by a cloud computing network, and or any components included therein, may be supported by one or more devices similar to device 1200. Stated otherwise, some or all of the operations performed by the cloud computing network, and or any components included therein, may be performed by one or more devices 1200 operating in a cloud-based arrangement.

By way of example, and not limitation, computer-readable storage media can include volatile and non-volatile, removable and non-removable media implemented in any method or technology. Computer-readable storage media includes, but is not limited to, RAM, ROM, erasable programmable ROM (“EPROM”), electrically-erasable programmable ROM (“EEPROM”), flash memory or other solid-state memory technology, compact disc ROM (“CD-ROM”), digital versatile disk (“DVD”), high definition DVD (“HD-DVD”), BLU-RAY, or other optical storage, magnetic cassettes, magnetic tape, magnetic disk storage or other magnetic storage devices, or any other medium that can be used to store the desired information in a non-transitory fashion.

As mentioned briefly above, the storage 1218 can store an operating system 1220 utilized to control the operation of the device 1200. According to one embodiment, the operating system comprises the LINUX operating system. According to another embodiment, the operating system comprises the WINDOWS® SERVER operating system from MICROSOFT Corporation of Redmond, Washington. According to further embodiments, the operating system can comprise the UNIX operating system or one of its variants. It should be appreciated that other operating systems can also be utilized. The storage 1218 can store other system or application programs and data utilized by the device 1200.

In various embodiment, the storage 1218 or other computer-readable storage media is encoded with computer-executable instructions which, when loaded into the device 1200, may transform it from a general-purpose computing system into a special-purpose computer capable of implementing the embodiments described herein. These computer-executable instructions may be stored as application 1222 and transform the device 1200 by specifying how the processor(s) 1204 can transition between states, as described above. In some embodiments, the device 1200 has access to computer-readable storage media storing computer-executable instructions which, when executed by the device 1200, perform the various processes described above with regard to FIGS. 1-11. In more embodiments, the device 1200 can also include computer-readable storage media having instructions stored thereupon for performing any of the other computer-implemented operations described herein.

In still further embodiments, the device 1200 can also include one or more input/output controllers 1216 for receiving and processing input from a number of input devices, such as a keyboard, a mouse, a touchpad, a touch screen, an electronic stylus, or other type of input device. Similarly, an input/output controller 1216 can be configured to provide output to a display, such as a computer monitor, a flat panel display, a digital projector, a printer, or other type of output device. Those skilled in the art will recognize that the device 1200 might not include all of the components shown in FIG. 12, and can include other components that are not explicitly shown in FIG. 12, or might utilize an architecture completely different than that shown in FIG. 12.

As described above, the device 1200 may support a virtualization layer, such as one or more virtual resources executing on the device 1200. In some examples, the virtualization layer may be supported by a hypervisor that provides one or more virtual machines running on the device 1200 to perform functions described herein. The virtualization layer may generally support a virtual resource that performs at least a portion of the techniques described herein.

In many embodiments, the device 1200 can include a liquid cooling management logic 1224. The liquid cooling management logic 1224 may control the operation of various components in the system, such as, but not limited to, the solenoid valves and the leak detection module, to optimize the performance of the on-board liquid cooling system. The liquid cooling management logic 1224 can also process data from these components, such as, but not limited to, thermal load measurements and leak detection signals, to make real-time adjustments to the operation of the on-board liquid cooling system based on the current conditions.

In a number of embodiments, the storage 1218 can include leak detection data 1228. The leak detection data 1228 may include real-time data about the presence or absence of coolant leaks within the on-board liquid cooling system, enabling prompt response to potential issues. The leak detection data 1228 can also be utilized to track the performance of the on-board liquid cooling system over time, helping to identify trends or patterns that may indicate a need for maintenance or system adjustments.

In various embodiments, the storage 1218 can include coolant flow rate data 1230. The coolant flow rate data 1230 may include real-time data about the rate at which coolant is flowing through the on-board liquid cooling system, which can be important for maintaining optimal operating temperatures. The coolant flow rate data 1230 can also be utilized to adjust the operation of the solenoid valves, allowing the on-board liquid cooling system to respond dynamically to changes in the thermal load of the devices.

In still more embodiments, the storage 1218 can include thermal load data 1232. The thermal load data 1232 may include real-time data about the amount of heat being generated by the devices in the enclosure, which can be important for managing the cooling needs of the device enclosure. The thermal load data 1232 can also be utilized to adjust the coolant flow rate, allowing the on-board liquid cooling system to optimize energy usage and maintain safe operating temperatures for the devices.

Finally, in many embodiments, data may be processed into a format usable by a machine-learning model 1226 (e.g., feature vectors), and or other pre-processing techniques. The machine-learning (“ML”) model 1226 may be any type of ML model, such as supervised models, reinforcement models, and/or unsupervised models. The ML model 1226 may include one or more of linear regression models, logistic regression models, decision trees, Naïve Bayes models, neural networks, k-means cluster models, random forest models, and/or other types of ML models 1226. The ML model 1226 may be configured to analyze historical data from the system, such as, but not limited to, the thermal load data and the coolant flow rate data, to predict future cooling needs and optimize the operation of the on-board liquid cooling system.

Although the present disclosure has been described in certain specific aspects, many additional modifications and variations would be apparent to those skilled in the art. In particular, any of the various processes described above can be performed in alternative sequences and/or in parallel (on the same or on different computing devices) in order to achieve similar results in a manner that is more appropriate to the requirements of a specific application. It is therefore to be understood that the present disclosure can be practiced other than specifically described without departing from the scope and spirit of the present disclosure. Thus, embodiments of the present disclosure should be considered in all respects as illustrative and not restrictive. It will be evident to the person skilled in the art to freely combine several or all of the embodiments discussed here as deemed suitable for a specific application of the disclosure. Throughout this disclosure, terms like “advantageous”, “exemplary” or “example” indicate elements or dimensions which are particularly suitable (but not essential) to the disclosure or an embodiment thereof and may be modified wherever deemed suitable by the skilled person, except where expressly required. Accordingly, the scope of the disclosure should be determined not by the embodiments illustrated, but by the appended claims and their equivalents.

Any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims.

Moreover, no requirement exists for a system or method to address each and every problem sought to be resolved by the present disclosure, for solutions to such problems to be encompassed by the present claims. Furthermore, no element, component, or method step in the present disclosure is intended to be dedicated to the public regardless of whether the element, component, or method step is explicitly recited in the claims. Various changes and modifications in form, material, workpiece, and fabrication material detail can be made, without departing from the spirit and scope of the present disclosure, as set forth in the appended claims, as might be apparent to those of ordinary skill in the art, are also encompassed by the present disclosure.

What is claimed is:

1. A device, comprising:
a processor;
at least one network interface controller configured to provide access to a network; and
a memory communicatively coupled to the processor, wherein the memory comprises a liquid cooling management logic that is configured to:
determine a condition of the device; and
adjust a state of one or more hydraulic solenoid valves to effect a change in a coolant flow in the device based on the determined condition of the device, wherein the device is associated with a liquid cooling system for a device enclosure that is mountable in a server rack.

2. The device of claim 1, wherein the processor is associated with a baseboard management controller.

3. The device of claim 1, wherein the device further comprises a leak detector, and wherein determining the condition of the device comprises detecting a coolant leak in the device based on the leak detector.

4. The device of claim 3, wherein adjusting the state of the one or more hydraulic solenoid valves to effect the change in the coolant flow comprises causing at least one of the one or more hydraulic solenoid valves to close to stop the coolant flow in the device based on the detected coolant leak.

5. The device of claim 4, wherein the leak detector comprises a single wire leak detector.

6. The device of claim 4, wherein the leak detector comprises a millimeter wave-based leak detector.

7. The device of claim 4, wherein the leak detector comprises a time-domain reflectometry-based leak detector.

8. The device of claim 4, wherein the leak detector comprises a vector network analyzer-based leak detector.

9. The device of claim 4, wherein the at least one of the one or more hydraulic solenoid valves comprises a hydraulic solenoid valve on a coolant inlet line of the device.

10. The device of claim 4, wherein the at least one of the one or more hydraulic solenoid valves comprises a first hydraulic solenoid valve on a coolant inlet line of the device and a second hydraulic solenoid valve on a coolant outlet line of the device.

11. The device of claim 1, wherein at least one of the one or more hydraulic solenoid valves are inside the device enclosure.

12. The device of claim 1, wherein at least one of the one or more hydraulic solenoid valves are outside the device enclosure.

13. The device of claim 1, wherein the device enclosure comprises a blade chassis.

14. The device of claim 1, wherein the device enclosure comprises a rack chassis.

15. The device of claim 1, wherein the device is associated with an open loop liquid cooling system.

16. The device of claim 1, wherein the condition of the device comprises a thermal load in the device enclosure, and wherein adjusting the state of the one or more hydraulic solenoid valves to effect the change in the coolant flow comprises adjusting the state of the one or more hydraulic solenoid valves to change a coolant flow rate based on the thermal load.

17. The device of claim 16, wherein the liquid cooling management logic is further configured to compare the thermal load to a threshold, and adjusting the state of the one or more hydraulic solenoid valves to change the coolant flow rate based on the thermal load further comprises reducing the coolant flow rate in response to the thermal load being less than the threshold.

18. A device, comprising:
a processor;
at least one network interface controller configured to provide access to a network; and
a memory communicatively coupled to the processor, wherein the memory comprises a liquid cooling management logic that is configured to:
detect a coolant leak in the device based on a leak detector; and
cause one or more hydraulic solenoid valves to close to stop a coolant flow in the device based on the detected coolant leak, wherein the device corresponds to a liquid cooling system for a device enclosure that is mountable in a server rack.

19. The device of claim 18, wherein the leak detector comprises a millimeter wave-based leak detector.

20. A method, comprising:
receiving an indication of a condition of a liquid cooling system associated with a device enclosure, wherein the device enclosure is mountable in a server rack;
determining whether the condition comprises at least one of a coolant leak or a change in a thermal load; and
transmitting a signal based on the determination to the liquid cooling system associated with the device enclosure.
